(19) United States
(12) Patent Application Publication
(10) Pub. No.: US 2007/0001094 A1
(43) Pub. Date: Jan. 4, 2007

(54) Infrared filter for imagers

(75) Inventor: Howard E. Rhodes, Sunnyvale, CA (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/168,759

(22) Filed: Jun. 29, 2005

(51) Int. Cl. H01L 27/00

(52) U.S. Cl. 250/208.1

(57) ABSTRACT

Imaging devices with an infrared filter over a surface of the substrate and methods for forming the same are provided. The imager includes a plurality of pixels supported by the substrate. Each pixel includes a photosensor. The imager may also include a plurality of micro-lenses and a color filter array with a plurality of filters, each filter being dedicated to a respective micro-lens. Over the substrate is an infrared filter for inhibiting the passage of infrared radiation to the photosensors.

### FIELD OF THE INVENTION

The present invention relates generally to the field of semiconductor imager devices, and more particularly to imager devices capable of blocking infrared radiation.

### BACKGROUND

The semiconductor industry currently manufactures different types of semiconductor-based imagers, such as charge coupled devices (CCDs), CMOS active pixel sensors (APS), photodiode arrays, charge injection devices and hybrid focal plane arrays, among others.

Current semiconductor-based imagers use a color filter array having an array of red, green and blue filters. Alternatively, cyan, magenta and yellow filters may be incorporated in the imagers. Certain specialized imagers, such as medical imagers, create images that are particularly susceptible to the effects of infrared radiation. For these imagers, it is important to suppress the amount of infrared radiation reaching the pixel cells.

One conventional semiconductor-based imager 10, shown in FIG. 1, includes an array of micro-lenses 12 mounted on a color filter array 14. The imager 10 is based on the concept that absorption of electromagnetic radiation by silicon depends on wavelength, the longer wavelengths penetrating further before being absorbed. The color filter array 14 includes a first color filter 14_{A}, a second color filter 14_{B}, and a third color filter 14_{C}. For example, the first color filter 14_{A} may be a blue filter, the second color filter 14_{B} may be a red filter, and the third color filter 14_{C} may be a green filter. Alternatively, cyan, magenta and yellow may be substituted for the blue, red and green filters.

The color filter array 14 and an insulating layer 15 are located on a wafer 16 in which pixel cells having photosensors 18 are embedded. The photosensors 18 are located at a depth in the wafer 16 shallow enough to receive short wavelength electromagnetic radiation 20 at an average absorption depth 22 at the photosensors 18 but not to receive infrared radiation 24, which has an average absorption depth 26 deeper in the wafer 16 than the photosensors 18. In other words, most of the infrared radiation 24 penetrates to a depth greater than the photosensors 18 before it is absorbed, producing free electrons.

The above-described conventional imager does not inhibit the effects of infrared radiation, but instead avoids sensing the infrared radiation by keeping the photosensors 18 away from the area at which the infrared radiation 24 creates free electrons in the silicon wafer 16. Thus, there remains a need in the industry to provide a semiconductor-based imager that inhibits infrared radiation effects.

### SUMMARY

Exemplary embodiments of the invention provide an imaging device that includes a plurality of photosensors supported by a substrate, and an infrared filter over the photosensors. The imager may further include a plurality of micro-lenses and a color filter array with a plurality of filters. The infrared filter inhibits the passage of infrared radiation to the photosensors. Exemplary embodiments of the invention also provide methods for forming such an imaging device.

These and other features of the invention will be more readily understood from the following detailed description of the invention which is provided in connection with the accompanying drawings.

### BRIEF DESCRIPTION OF THE DRAWINGS

FIG. 1 is a cross-sectional view of a conventional imager.

FIG. 2A is a cross-sectional view of an imager constructed in accordance with an exemplary embodiment of the invention.

FIG. 2B is a cross-sectional view of an imager constructed in accordance with another exemplary embodiment of the invention.

FIG. 3 illustrates a block diagram of an integrated circuit including the imager of FIG. 2.

FIG. 4 illustrates a schematic diagram of a computer processor system including the imager of FIG. 2.

FIG. 5 illustrates a process for forming the imager of FIG. 2.

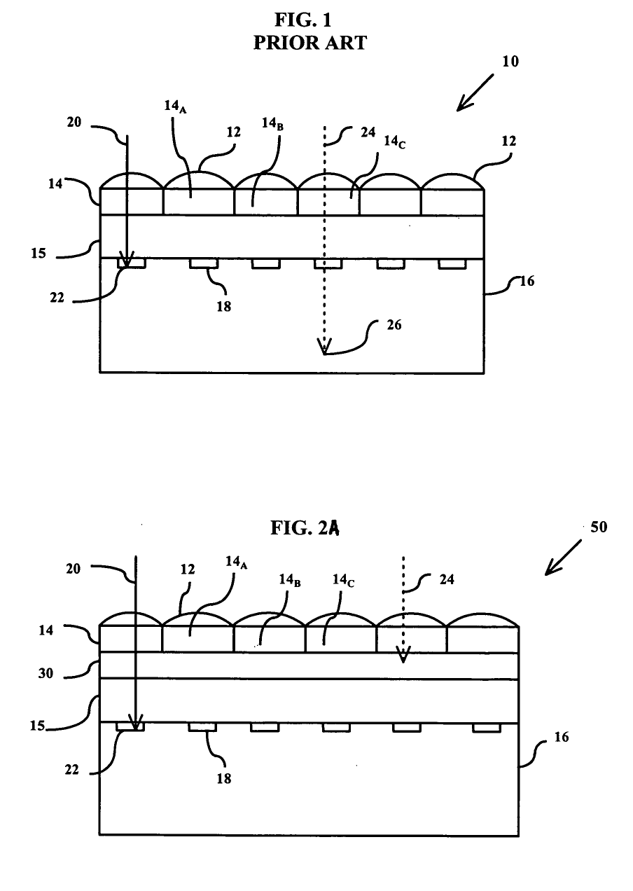

### DETAILED DESCRIPTION OF PREFERRED EMBODIMENTS

In the following detailed description, reference is made to the accompanying drawings, which form a part hereof and show by way of illustration specific embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order.

The terms “wafer” and “substrate,” as used herein, are to be understood as including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor need not be silicon-based, but could be based on silicon-germanium, germanium, gallium arsenide or other semiconductors.

The term “pixel,” as used herein, refers to a photo-element unit cell containing a photosensor or photo-conversion device and associated transistors for converting photons to an electrical signal. For purposes of illustration, a single representative two-color pixel and its manner of formation is shown in the figures and description herein; however, typically fabrication of a plurality of like pixels proceeds simultaneously. Accordingly, the following detailed description is not to be taken in a limiting sense, and the scope of the present invention is defined only by the appended claims.

While the invention is described with reference to a CMOS imager, it should be appreciated that the invention may be applied in any micro-electronic or micro-optical device. Other suitable micro-optical devices include, but are not limited to CCDs and displays.

Referring now to FIG. 2A, a portion of a semiconductor-based imager 50 is shown including an array of micro-lenses 12, a color filter array 14, a blanket infrared filter 30, an insulating layer 15, and a substrate or wafer 16, which may be a silicon wafer. Each micro-lens 12 has a dedicated color filter in the color filter array (CFA) 14. For example, one micro-lens 12 has a first color filter 14_{A}, which may be a blue filter, another micro-lens 12 has a second color filter 14_{B}, which may be a red filter, and a third micro-lens 12 has a third color filter 14_{C}, which may be a green filter.

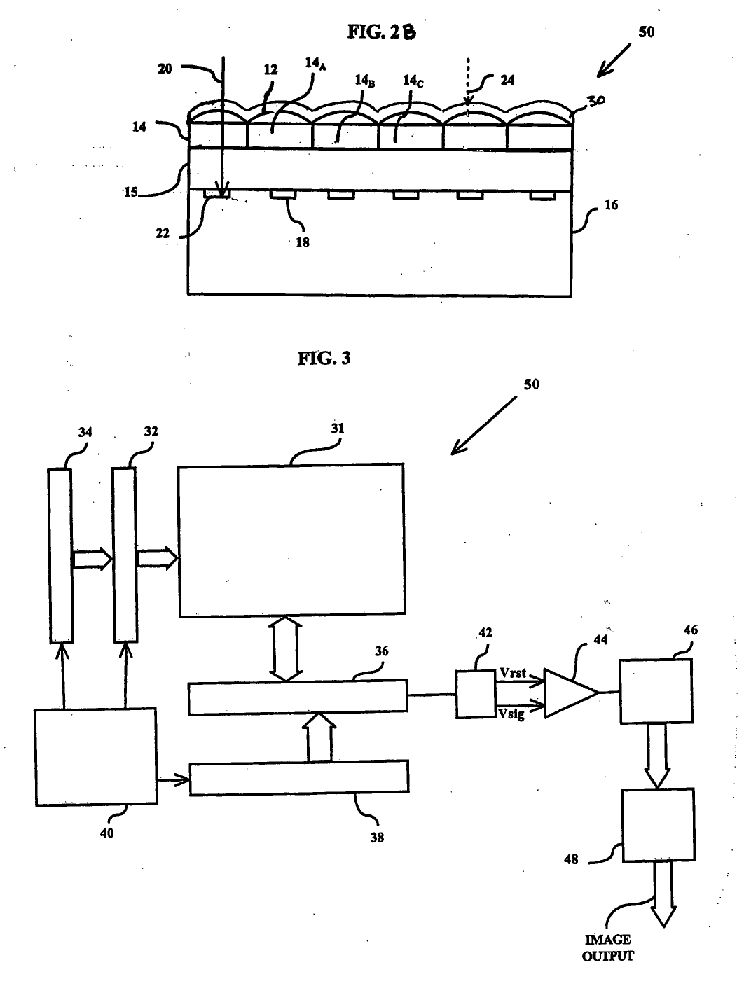

The blanket infrared filter 30 is formed of a material which is suitable for blocking infrared radiation 24, i.e., the material has the desired spectral absorption and transmission characteristics to make it opaque to infrared radiation, which is defined herein as radiation at wavelengths above 780 nm. Organic or inorganic films may be used as the blanket infrared filter 30. An exemplary inorganic film material may be a doped oxide film, such as, for example, a doped oxide of silicon. As shown in FIG. 2A, the majority of infrared radiation 26 radiates through the micro-lenses 12 and CFA 14 but is absorbed by the blanket infrared filter 30. The blanket infrared filter 30 is, however, transparent to shorter wavelength visible electromagnetic radiation 20. Visible radiation 20, therefore, reaches the photosensors 18 where it is absorbed and produces free electrons. The imager 50 also includes readout circuitry (FIG. 3) for reading out signals indicating radiation sensed by the photosensors 18.

While it is shown in FIG. 2A that the blanket infrared filter 30 is situated between the CFA 14 and the wafer substrate 16, it should be understood that the CFA 14 instead may be positioned between the blanket infrared filter 30 and the wafer 16. Additionally, depending on the infrared filter deposition characteristics (such as deposition temperature and thickness), it is possible that the filter 30 can be applied above and conformal with the micro-lenses 12, as shown in FIG. 2B. One advantage of depositing the blanket infrared filter 30 over the micro-lenses 12 is that it does not add to the overall stack height (distance between the wafer substrate 16 and the micro-lenses 12).

While FIGS. 2A and 2B show a CFA 14 and micro-lenses 12, it should be understood that for some applications, the CFA 14 and/or micro-lenses 12 may not be desirable and one or both can be excluded.

FIG. 3 illustrates a block diagram of an integrated circuit including the imager 50 with a pixel array 31 containing a plurality of pixels arranged in rows and columns. The pixels of each row in the pixel array 31 are all turned on at the same time by a row select line (not shown), and the pixels of each column are selectively output by respective column select lines (not shown).

The row lines are selectively activated by a row driver 32 in response to row address decoder 34. The column select lines are selectively activated by a column selector 36 in response to column address decoder 38. The pixel array 31 is operated by the timing and control circuit 40, which controls address decoders 34, 38 for selecting the appropriate row and column lines for pixel signal readout.

The pixel column signals, which typically include a pixel reset signal (Vᵣₛₜ) and a pixel image signal (V_{sjg}), are read by a sample and hold circuit 42 associated with the column selector 36. A differential signal (Vᵣₛₜ−V_{sjg}) is produced by a differential amplifier 44 for each pixel which is amplified and digitized by an analog to digital converter 46 (ADC). The analog to digital converter 46 supplies the digitized pixel signals to an image processor 48 which can perform image processing in which signals read out from pixels are treated as levels of detected light intensity. The resulting pixel values can be provided to other components to define an output image.

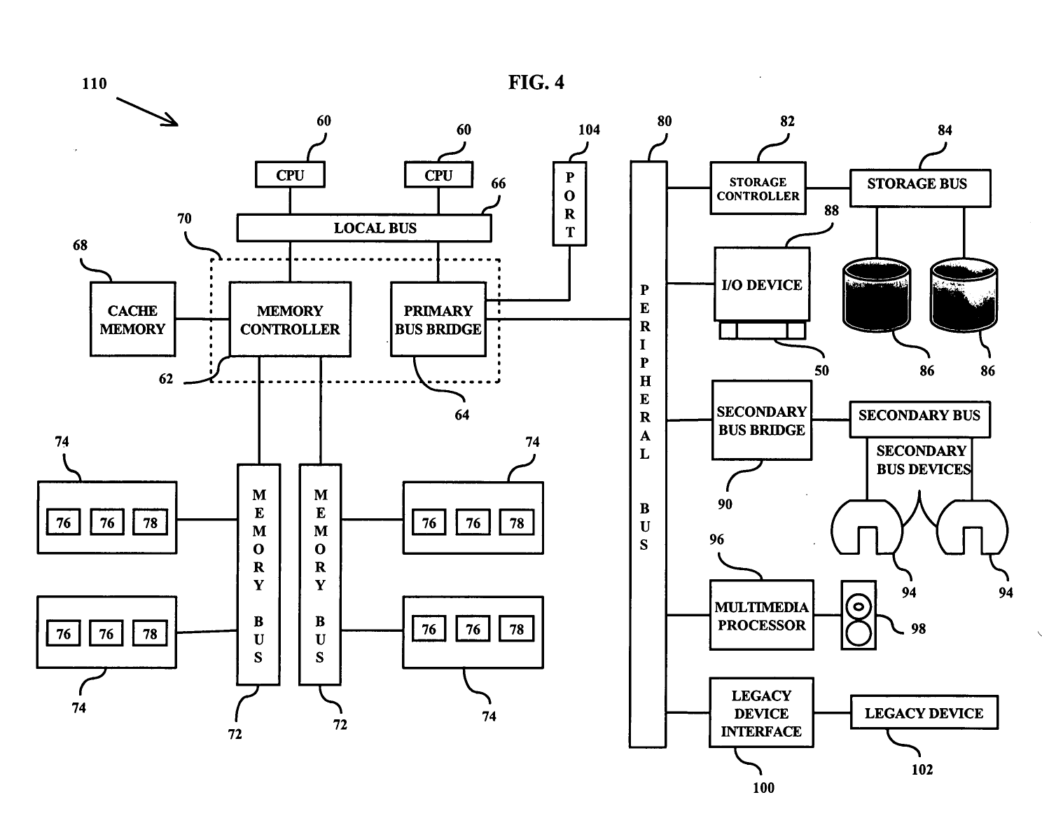

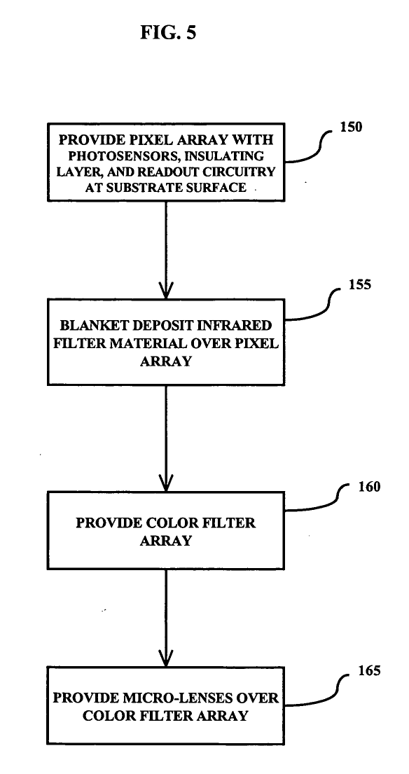

If desired, the imager 50 described above with respect to FIG. 3 may be combined with other components in a single integrated circuit. FIG. 4 illustrates an exemplary processing system 110 which includes the imager 50. It should be appreciated that instead the processing system 110 may include another imaging device incorporating features illustrated in FIG. 3.

As illustrated in FIG. 4, the processing system 110 includes one or more processors 60 coupled to a local bus 66. A memory controller 62 and a primary bus bridge 64 are also coupled to local bus 66. The processing system 110 may include multiple memory controllers 62 and/or multiple primary bus bridges 64. The memory controller 62 and the primary bus bridge 64 may be integrated as a single device 70.

The memory controller 62 is also coupled to one or more memory buses 72. Each memory bus 72 accepts memory components 74 which include at least one memory device 76. The memory components 74 may be a memory card or a memory module. Examples of memory modules include single inline memory modules (SIMMs) and dual inline memory modules (DIMMs). The memory components 74 may include one or more additional devices 78. For example, in a SIMM or DIMM, the additional device 78 might be a configuration memory, such as a serial presence detect (SPD) memory. The memory controller 62 may also be coupled to a cache memory 68. The cache memory 68 may be the only cache memory in the processing system 110. Alternatively, other devices, for example, processors 60 may also include cache memories, which may form a cache hierarchy with cache memory 68. If the processing system 110 includes peripherals or controllers which are bus masters or which support direct memory access (DMA), the memory controller 62 may implement a cache coherency protocol. If the memory controller 62 is coupled to a plurality of memory buses 72, each memory bus 72 may be operated in parallel, or different address ranges may be mapped to different memory buses 72.

The primary bus bridge 64 is coupled to at least one peripheral bus 80. Various devices, such as peripherals or additional bus bridges may be coupled to the peripheral bus 80. These devices may include a storage controller 82, miscellaneous I/O device 88, a secondary bus bridge 90, a multimedia processor 96, and legacy device interface 100. The primary bus bridge 64 may also be coupled to one or more special purpose high speed ports 104. In a personal computer, for example, the special purpose port might be the Accelerated Graphics Port (AGP), used to couple a high performance video card to the processing system 110.

The storage controller 82 couples one or more storage devices 86, via a storage bus 84, to the peripheral bus 80. For example, the storage controller 82 may be a SCSI controller and storage devices 86 may be SCSI discs. The I/O device 88 may be an imaging device that includes the imager 50. The processing system 110 could include any other sort of I/O peripheral device. For example, the I/O device 88 may be a local area network interface, such as an Ethernet card. The secondary bus bridge 90 may be used to interface additional devices via another bus to the processing system. For example, the secondary bus bridge 90 may be a universal serial port (USB) controller used to couple USB devices 94 via to the processing system 110. The multimedia processor 96 may be a sound card, a video capture card, or any other type of media interface, which may also be coupled to additional devices such as speakers 98. The legacy device interface 100 is used to couple legacy devices 102, for example, older styled keyboards and mice, to the processing system 110.

The processing system 110 illustrated in FIG. 4 is only an exemplary processing system with which the invention may be used. While FIG. 4 illustrates a processing architecture especially suitable for a general purpose computer, such as a workstation, it should be recognized that well known modifications can be made to configure the processing system 110 to become more suitable for use in a variety of applications. For example, many electronic devices which require processing may be implemented using a simpler architecture which relies on a CPU 60 coupled to memory components 74 and/or memory devices 76. These electronic devices may include, but are not limited to audio/video processors and recorders, gaming consoles, digital television sets, wired or wireless telephones, navigation devices (including system based on the global positioning system (GPS) and/or inertial navigation), and digital cameras and/or recorders. CMOS imager devices that include embodiments of the present invention, when coupled to a pixel processor, for example, may be implemented in color or monochrome digital cameras and video processors and recorders. Modifications may include, for example, elimination of unnecessary components, addition of specialized devices or circuits, and/or integration of a plurality of devices.

Referring now to FIG. 5, next will be described a process for forming the imager 50. At Step 150, operations are performed that produce the pixel array 31 at the surface of the substrate 16. The pixel array 31 includes an array of photosensors 18, readout circuitry that provides readout signals from the photosensors 18, and an insulating structure over the photosensors 18 and the readout circuitry. The insulating structure can include the insulating layer 15 and other appropriate layers.

At Step 155, the blanket infrared filter 30 is provided over a surface of the wafer 16 by performing a blanket deposition of infrared filter material over the pixel array 31. One process for providing the blanket infrared filter 30 over the wafer 16 is by growing a suitable doped layer of a silicon oxide. The deposition of the blanket infrared filter 30 over the wafer substrate 16 is potentially beneficial in reducing overall manufacturing costs compared to the industry standard approach of incorporating it into the external packaging (either as a separate filter or as a coating on the external lens). At Step 160, the color filter array (CFA) 14 is produced. The CFA 14 may be produced, for example, by depositing and photolithographically patterning filter layers, such as red, blue, green and clear layers.

Finally, at Step 165, the micro-lenses 12 are produced over the CFA 14. The micro-lenses 12 may be produced, for example, by depositing and patterning a layer of lens material and then baking to produce a suitable lens shape over each of the photosensors 18. Further operations can be performed to complete assembly of the imager 50.

It also should be understood that the order of the process may be altered. For example, Step 155 may precede or follow Step 160 or 165; or Step 155, with 160, and/or 165 may be accomplished by a single sequence of operations.

While the invention has been described in detail in connection with exemplary embodiments known at the time, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Accordingly, the invention is not to be seen as limited by the foregoing description, but is only limited by the scope of the appended claims.

1. An imaging device, comprising:
a plurality of photosensors supported by a substrate; and
a blanket deposited infrared filter layer comprising doped silicon oxide arranged over the photosensors.

2. The device of claim 1, further comprising an insulating structure arranged over the photosensors, the infrared filter located being arranged on the insulating structure.

3. (canceled)

4. The device of claim 1, in which the infrared filter layer absorbs a majority of radiation at wavelengths greater than 780 nm.

5. The device of claim 1, further comprising a color filter array arranged over the infrared filter.

6. The device of claim 1, further comprising an array of micro-lenses arranged over the infrared filter, the array of micro-lenses including a respective micro-lens for each said photosensor.

7. The device of claim 1, further comprising an array of micro-lenses, the infrared filter being arranged over the micro-lenses.

8. The device of claim 1, further comprising a color filter array, the infrared filter being arranged over the color filter array.

9. An imager, comprising:
a plurality of micro-lenses;
a substrate supporting a plurality of pixel cells, each said pixel cell including a photosensor; and
a blanket deposited layer of infrared blocking material positioned over said substrate,
wherein the material comprises a doped oxide of silicon.

10-11. (canceled)

12. The imager of claim 9, wherein the layer of infrared blocking material is a conformal layer over the micro-lenses.

13. The imager of claim 9, wherein the layer of infrared blocking material is below the micro-lenses.

14. The imager of claim 9, wherein the infrared blocking material absorbs a majority of radiation at wavelengths greater than 780 nm.

15. A method of producing an imager, the method comprising the acts of:
forming at least one pixel comprising a photosensor on a substrate; and
forming an infrared filter structure over the pixel cell by blanket deposition, wherein the infrared filter structure comprises a doped layer of silicon oxide.

16. The method of claim 15, further comprising the act of forming an insulating structure over the pixel cell, the infrared filter structure being formed over the insulating structure.

17. (canceled)

18. The method of claim 15, further comprising the act of forming at least one color filter over the infrared filter structure.

19. The method of claim 15, further comprising the act of forming at least one micro-lens over the infrared filter structure.

20. The method of claim 15, further comprising the act of forming a color filter over the photosensor, wherein the act of forming the infrared filter structure comprises forming the infrared filter structure over the color filter.

21. The method of claim 15, further comprising the act of forming a micro-lenses over the photosensor, wherein the act of forming the infrared filter structure comprises forming the infrared filter structure conformally over the micro-lens.

22. The method of claim 15, wherein the act of forming the at least one pixel comprises forming a plurality of pixels.

23. A method of forming an imager, the method comprising the acts of:
providing a substrate supporting a plurality of pixels, each pixel including a photosensor;
forming an infrared filter comprising doped oxide of silicon over the photosensors by blanket deposition; and
forming a plurality of micro-lenses over the photosensors.

24. The method of claim 23, wherein the doped oxide of silicon is opaque to infrared radiation.

25-26. (canceled)

27. A processing system, comprising:
a processor; and
an imaging device connected for exchanging signals with the processor, the imaging device comprising:
a substrate;
a pixel array formed at a surface of the substrate, the pixel array comprising an array of photosensors; and
a blanket deposited infrared filter structure arranged over the pixel array, said infrared filter structure comprising doped silicon oxide.

28. The processing system of claim 27, in which the pixel array further comprises an insulating structure over the photosensors, the infrared filter structure being located over the insulating structure.

29. (canceled)

30. The processing system of claim 27, in which the infrared filter structure absorbs a majority of radiation at wavelengths greater than 780 nm.

31. The processing system of claim 27, further comprising a color filter array over the infrared filter structure.

32. The processing system of claim 27, further comprising an array of micro-lenses over the infrared filter structure, the array of micro-lenses including a respective micro-lens for each said photosensor.

33. The processing system of claim 27, further comprising a color filter array under the infrared filter structure.

34. (canceled)

35. The processing system of claim 27, wherein the imaging device is a CCD type imaging device.

36. The processing system of claim 27, wherein the imaging device is a CMOS imaging device.

37. The imager of claim 9, further comprising a color filter array having a plurality of color filters, each color filter being dedicated to a respective photo sensor.

38. The method of claim 23, further comprising forming a color filter array having a plurality of color filters over the photosensors, wherein each of the color filters is dedicated to a respective photosensor.

39. An imager, comprising:
a substrate supporting a plurality of pixel cells, each said pixel cell including a photosensor;
a color filter array having a plurality of color filters, each respectively associated with a photosensor; and
a blanket deposited layer of infrared blocking material positioned over said pixel cells and comprising a doped oxide of silicon.

40. The imager of claim 39, further comprising a plurality of micro-lenses, respectively associated with said plurality of color filters.

41. The device of claim 39, in which the infrared blocking material absorbs a majority of radiation at wavelengths greater than 780 nm.

42. The device of claim 39, wherein the color filter array is arranged over the layer of infrared blocking material.

43. The device of claim 39, wherein the layer of infrared blocking material is arranged over the color filter array.
